(19) United States
(12) Patent Application Publication
(10) Pub. No.: US 2020/0045835 A1
(43) Pub. Date: Feb. 6, 2020

(54) REMOTE CONTROL DEVICE AND HOUSING ASSEMBLY

(71) Applicant: SZ DJI TECHNOLOGY CO., LTD., Shenzhen (CN)

(72) Inventor: Kunpeng JING, Shenzhen (CN)

(21) Appl. No.: 16/596,248

(22) Filed: Oct. 8, 2019

Related U.S. Application Data
(63) Continuation of application No. PCT/CN2017/088134, filed on Jun. 13, 2017.

(30) Foreign Application Priority Data
Apr. 25, 2017 (CN) 201720437095.2

(51) Int. Cl. H05K 5/00; H05K 5/03; G06F 3/0338

(52) U.S. Cl. CPC H05K 5/0013; G05D 1/0016; G06F 3/0338; H05K 5/03

(57) ABSTRACT

A housing assembly for a remote control device includes a housing. The housing includes an opening. A first snap-fit mechanism is provided on an inner wall of the opening. The housing assembly also includes a cover assembly including a second snap-fit mechanism. The second snap-fit mechanism is configured to snap-fit with the first snap-fit mechanism to cause the cover assembly to cover the opening of the housing. At least one of the first snap-fit mechanism or the second snap-fit mechanism is an elastic snap-fit mechanism. When under an external force, at least one of the first snap-fit mechanism or the second snap-fit mechanism elastically deforms to release a snap-fit state to cause the cover assembly to separate from the housing.

### CROSS-REFERENCE TO RELATED APPLICATIONS

This application is a continuation application of International Application No. PCT/CN2017/088134, filed on Jun. 13, 2017, which claims priority to Chinese Patent Application No. 201720437095.2, filed on Apr. 25, 2017, the entire contents of both of which are incorporated herein by reference.

### TECHNICAL FIELD

The present disclosure relates to the technology field of unmanned aerial vehicles and, more particularly, to a remote control device and a housing assembly included in the remote control device.

### BACKGROUND

An unmanned aerial vehicle (“UAV”) may be controlled by operations on a joystick provided on a remote control device. The joystick of the remote control device is typically provided inside a housing of the remote control device and extends to the outside of the housing. A cover assembly for the joystick may be fixedly connected with the housing. The joystick may penetrate through the cover assembly and be exposed to the outside of the housing. A gap may exist between the joystick and the cover assembly to provide an operating space for the joystick. However, as the remote control device is used over time, dusts may enter the housing through the gap.

In the existing technologies, because the housing and the cover assembly are fixedly connected, it is not convenient to disassemble the cover assembly from the housing for cleaning the dusts accumulated inside the housing.

### SUMMARY

In accordance with an aspect of the present disclosure, there is provided a housing assembly for a remote control device. The housing assembly includes a housing. The housing includes an opening. A first snap-fit mechanism is provided on an inner wall of the opening. The housing assembly also includes a cover assembly including a second snap-fit mechanism. The second snap-fit mechanism is configured to snap-fit with the first snap-fit mechanism to cause the cover assembly to cover the opening of the housing. At least one of the first snap-fit mechanism or the second snap-fit mechanism is an elastic snap-fit mechanism. When under an external force, at least one of the first snap-fit mechanism or the second snap-fit mechanism elastically deforms to release a snap-fit state to cause the cover assembly to separate from the housing.

In accordance with another aspect of the present disclosure, there is also provided a remote control device. The remote control device includes a housing assembly. The housing assembly includes a housing including an opening. A first snap-fit mechanism is provided on an inner wall of the opening. The housing assembly also includes a cover assembly including a second snap-fit mechanism. The second snap-fit mechanism is configured to snap-fit with the first snap-fit mechanism to cause the cover assembly to cover the opening of the housing. At least one of the first snap-fit mechanism or the second snap-fit mechanism is an elastic snap-fit mechanism. When under an external force, at least one of the first snap-fit mechanism or the second snap-fit mechanism elastically deforms to release a snap-fit state to cause the cover assembly to separate from the housing.

Advantages of the technical solutions of the present disclosure may include: compared to existing technologies, the present disclosure provides a first snap-fit mechanism on an inner wall of an opening of the housing, and a second snap-fit mechanism at the cover assembly. The first snap-fit mechanism and/or the second snap-fit mechanism may be elastic snap-fit mechanisms. The cover assembly and the housing may be connected through snap-fitting the first snap-fit mechanism and the second snap-fit mechanism. When under an external force, the first snap-fit mechanism and/or the second snap-fit mechanism may undergo elastic deformation to release the snap-fitting state and to separate from one another. Thus, the disclosed structure renders it convenient to mount a dust cover for blocking dusts from entering the housing. When the dust cover needs to be replaced, the disclosed structure renders it easy to disassemble and replace the dust cover. When the dust cover is removed from the cover assembly, it is convenient to mount the cover assembly to the housing and to disassemble the cover assembly for cleaning the dusts from the inside of the housing.

### BRIEF DESCRIPTION OF THE DRAWINGS

To better describe the technical solutions of the various embodiments of the present disclosure, the accompanying drawings showing the various embodiments will be briefly described. As a person of ordinary skill in the art would appreciate, the drawings show only some embodiments of the present disclosure. Without departing from the scope of the present disclosure, those having ordinary skills in the art could derive other embodiments and drawings based on the disclosed drawings without inventive efforts.

FIG. 1 is a partial exploded view of a housing assembly of a remote control device, according to an example embodiment.

FIG. 2 is a perspective view of a portion of the housing assembly shown in FIG. 1, according to an example embodiment.

FIG. 3 is a schematic view of a first snap-fit mechanism shown in FIG. 2, according to an example embodiment.

FIG. 4 is an exploded view of a covering assembly shown in FIG. 1, according to an example embodiment.

FIG. 5 is a schematic illustration of a first state when the cover assembly is rotated into a housing, according to an example embodiment.

FIG. 6 is a schematic illustration of a second state when the cover assembly is rotated into the housing, according to an example embodiment.

FIG. 7 is a perspective view of an assembled remote control device of FIG. 1, according to an example embodiment.

FIG. 8 is a schematic illustration of a first state when the cover assembly is separated from the housing, according to an example embodiment.

FIG. 9 is a schematic illustration of a second state when the cover assembly is separated from the housing, according to an example embodiment.

### DETAILED DESCRIPTION OF THE EMBODIMENTS

Technical solutions of the present disclosure will be described in detail with reference to the drawings, in which the same numbers refer to the same or similar elements unless otherwise specified. It will be appreciated that the described embodiments represent some, rather than all, of the embodiments of the present disclosure. Other embodiments conceived or derived by those having ordinary skills in the art based on the described embodiments without inventive efforts should fall within the scope of the present disclosure.

Embodiments of the present disclosure shown in the drawings will be described in detail below. When describing the accompanying drawings, unless otherwise noted, the same reference number in different drawings indicate the same or similar elements. The embodiments described below do not represent all of the possible embodiments of the present disclosure. Instead, the embodiments described below are only some devices and methods that are consistent with various aspects of invention defined by the claims.

The terms used in the following descriptions are only for the purpose of describing specific embodiments, and are not intended to limit the scope of the present disclosure. In addition, the singular forms “a,” “an,” and “the” are intended to include the plural forms as well, unless the context indicates otherwise.

It should be understood that in the present disclosure, relational terms such as first and second, etc., are only used to distinguish an entity or operation from another entity or operation, and do not necessarily imply that there is an actual relationship or order between the entities or operations. Similarly, “a” or “one” and similar terms do not limit the number of features, but only indicate that there exists at least one feature. In addition, unless otherwise noted, the terms “front,” “back” (or “rear”), “lower,” and/or “upper” and other similar terms are only for the convenience of descriptions, and are not intended to limit to a particular position, location, or space orientation. The terms “comprise,” “comprising,” “include,” and the like specify the presence of stated features, steps, operations, elements, and/or components appearing following these terms are included in an element or object appearing before these terms, but do not preclude the presence or addition of one or more other features, steps, operations, elements, components, and/or groups. When a first component is referred to as “connected” to or with a second component, it is intended that the first component may be directly connected to or with the second component or may be indirectly connected to or with the second component via an intermediate component. The connection may include mechanical and/or electrical connections. The connection may be permanent or detachable. The electrical connection may be wired or wireless.

The term “and/or” used herein includes any suitable combination of one or more related items listed. For example, A and/or B can mean A only, A and B, and B only. The symbol “/” means “or” between the related items separated by the symbol. The phrase “at least one of” A, B, or C encompasses all combinations of A, B, and C, such as A only, B only, C only, A and B, B and C, A and C, and A, B, and C. In this regard, A and/or B can mean at least one of A or B.

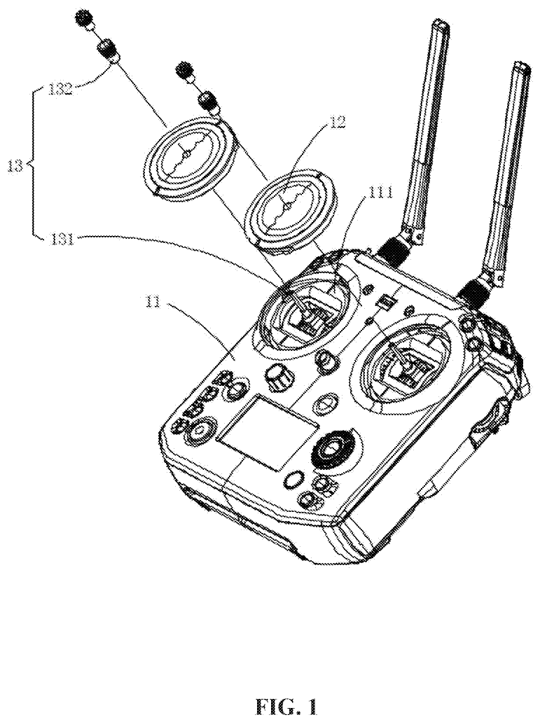

As shown in FIG. 1, a housing assembly of a remote control device according to the present disclosure may include a housing 11 and a cover assembly 12.

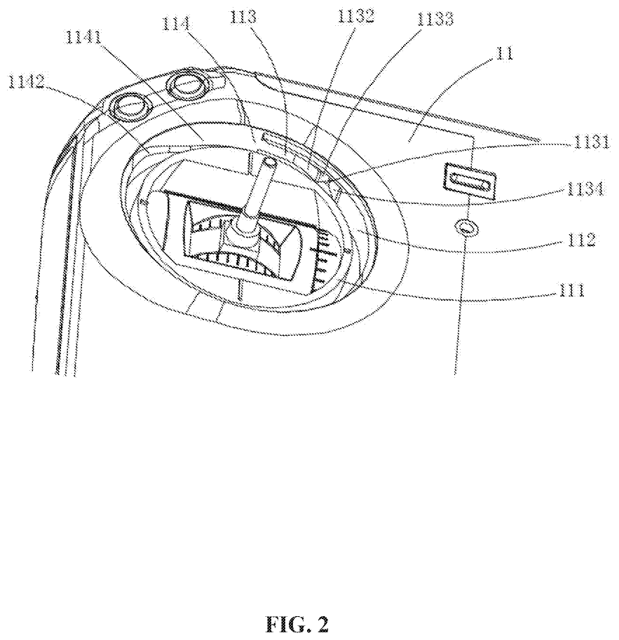

As shown in FIG. 2, the housing 11 may include one or more openings 111. Each opening 111 may include a circular shape and may extend into an inside of the housing 11. The opening 111 includes an inner wall 112 extending from the opening 111 to an inside of the housing 11.

The inner wall 112 may include a first snap-fit mechanism 113 disposed at the opening 111. In some embodiments, the first snap-fit mechanism 113 may be an elastic snap-fit mechanism.

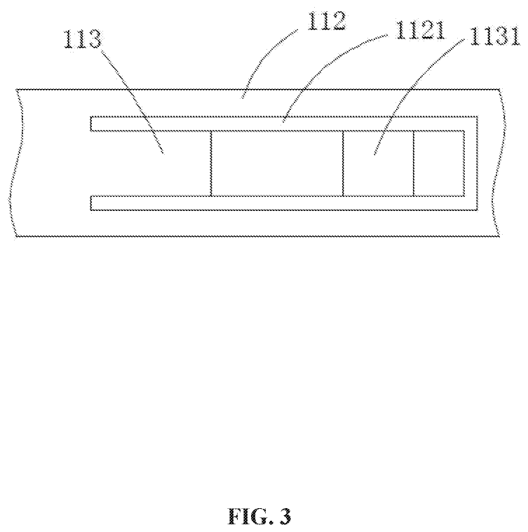

As shown in FIG. 2 and FIG. 3, the inner wall 112 may include an opening 1121 on the wall. The first snap-fit mechanism 113 may be disposed in the opening 1121. An end of the first snap-fit mechanism 113 may be fixedly connected with the inner wall 112. Another end of the first snap-fit mechanism 113 may undergo elastic deformation relative to the inner wall 112 when under an external force. As shown in FIG. 1, when under an external force, the first snap-fit mechanism 113 may undergo a radial elastic deformation relative to the inner wall 112 in a direction away from the opening 111.

The first snap-fit mechanism 113 may include a first snap-fit part 1131. The first snap-fit part 1131 may be provided at an end of the first snap-fit mechanism 113 that may undergo elastic deformations. In some embodiments, the first snap-fit part 1131 may include a snap-fit groove. In some embodiments, the first snap-fit part 1131 may include a snap-fit hook.

In some embodiments, the snap-fit groove of the first snap-fit part 1131 may include two first radially slanted guiding surfaces 1132 and 1133.

In some embodiments, the snap-fit groove of the first snap-fit part 1131 may include a blocking surface 1134.

In some embodiments, the inner wall 112 of the opening 111 may include a circumferential guiding groove 114 that is concavely disposed on the wall. An end of the guiding groove 114 may be provided with an entry/exit port 1141. Another end of the guiding groove 114 may be connected with the snap-fit groove of the first snap-fit mechanism 1131.

In some embodiments, a side of a side wall of the entry/exit port 1141 that faces an outside of the housing 11 is provided with a first axially slanted guiding surface 1142.

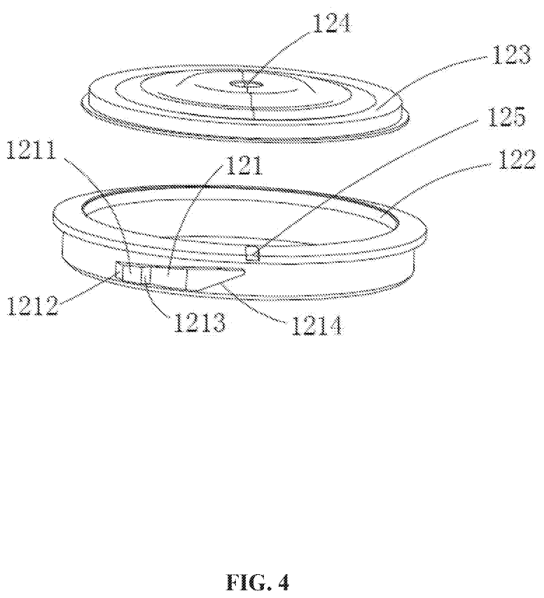

As shown in FIG. 4, the cover assembly 12 may include a second snap-fit mechanism 121. The second snap-fit mechanism 121 may be concavely disposed on a circumferential side surface of the cover assembly 12.

In some embodiments, the cover assembly 12 may include a hollow body 122 that may be configured as a ring shape. The second snap-fit mechanism 121 may be fixed to the hollow body 122 and protrude from a circumferential side surface of the hollow body 122.

In some embodiments, the second snap-fit mechanism 121 may include a second snap-fit part 1211. In some embodiments, the second snap-fit part 1211 may be a snap-fit hook configured to couple with the first snap-fit part 1131. In some embodiments, when the first snap-fit part 1131 is a snap-fit groove, the second snap-fit part 1211 is a snap-fit hook configured to couple with the snap-fit groove.

In some embodiments, the snap-fit hook of the second snap-fit part 1211 may be provided with two second radially slanted guiding surfaces 1212 and 1213. In some embodiments, the snap-fit part 121 may include a second axially slanted guiding surface 1214.

In some embodiments, the second snap-fit mechanism 121 may be an elastic snap-fit mechanism. The operating principle of the second snap-fit mechanism 121 may be similar to or the same as that of the first snap-fit mechanism, which may also be an elastic snap-fit mechanism. In some embodiments, the first snap-fit mechanism 113 and the second snap-fit mechanism 121 may both be elastic snap-fit mechanisms.

In some embodiments, the cover assembly 12 may include a dust cover 123 covering the hollow body 122. The dust cover 123 may include a through hole 124.

In some embodiments, the dust cover 123 may be an elastic dust cover, such as a rubber rust cover.

In some embodiments, a force bearing member 125 may be provided on the hollow body 122 or the dust cover 123. The force bearing member 125 may be configured to receive an external force. In the embodiment shown in FIG. 4, the force bearing member 125 is provided on the hollow body 122.

Referring to FIG. 1, the housing assembly may include a joystick assembly 13. The joystick assembly 13 may include a first stick body 131 and a second stick body 132.

An end of the first stick body 131 may be fixedly disposed in the opening 111 of the housing 11. Another end of the first stick body 131 may extend to outside of the housing 11 through the opening 111. A diameter of at least a portion of the first stick body 131 is smaller than a diameter of the through hole 124 of the cover assembly 12. An end of the second stick body 132 may be provided with an axial mounting hole (not shown in the figures).

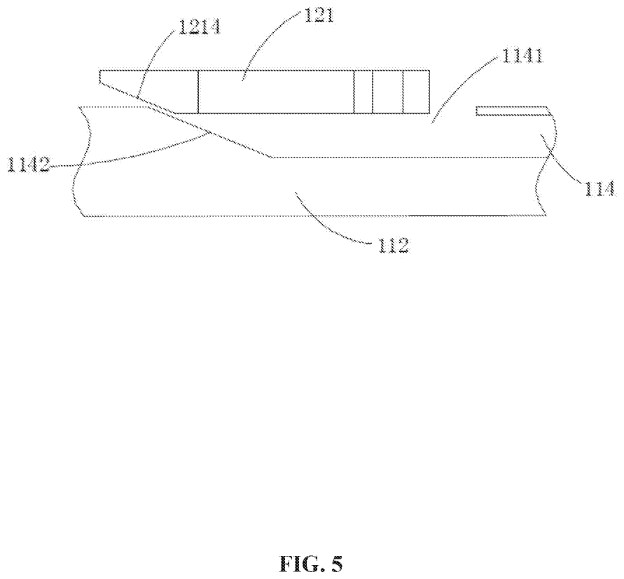

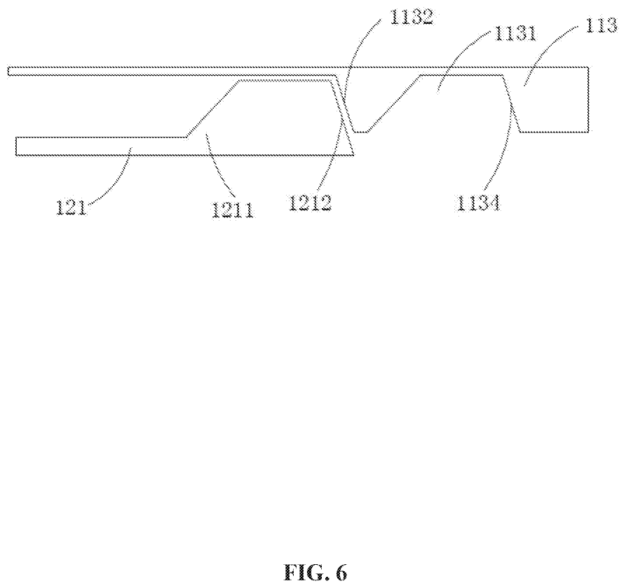

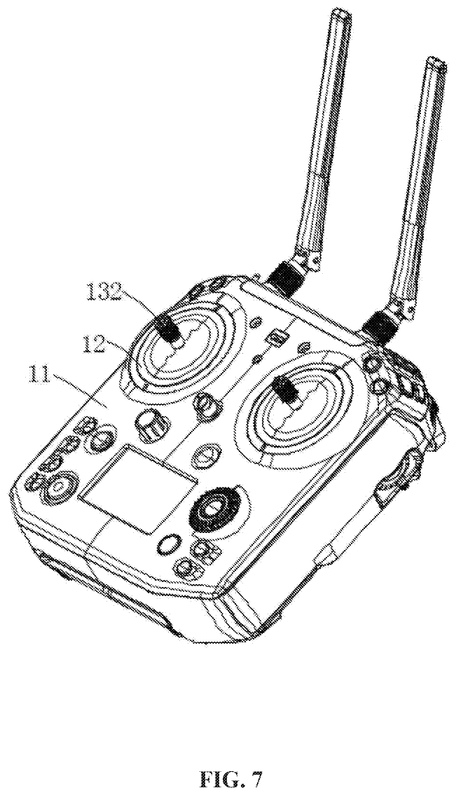

Referring to FIG. 1-FIG. 9, the first stick body 131 may penetrate through the through hole 124 of the cover assembly 12 in a direction along the dashed line shown in FIG. 1, and to cause the cover assembly 12 to be rotated into the opening of the housing 11. As shown in FIG. 5, rotating the cover assembly 12 may make the second snap-fit mechanism 121 to be located at the entry/exit port 1141. At this state, when the cover assembly 12 is further rotated in in a right-ward rotating-in direction, the first axially slanted guiding surface 1142 disposed at a side of the side wall of the entry/exit port 1141 that faces an outside of the housing 11 may abut against the second axially slanted guiding surface 1214. Under the abutting force, the second snap-fit mechanism 121 may be rotated toward the inside of the housing 11 into the guiding groove 114. In some embodiments, only one of the first axially slanted guiding surface 1142 and the second axially slanted guiding surface 1214 may be provided. When only the first axially slanted guiding surface 1142 is provided, the second snap-fit mechanism 121 may be rotated toward the inside of the housing 11 into the guiding groove 114 when under the abutting force from the first axially slanted guiding surface 1142. When only the second axially slanted guiding surface 1214 is provided, the second snap-fit mechanism 121 may rotate toward the inside of the housing 11 into the guiding groove 114 under the abutting force caused by the second axially slanted guiding surface 1213 abutting against the side wall of the entry/exit port 1141. As shown in FIG. 6, the cover assembly 12 may be further rotated in the rotating-in direction until the second snap-fit part 1211 of the second snap-fit mechanism 121 touches the first snap-fit part 1131 of the first snap-fit mechanism 113. When the cover assembly 12 is further rotated, the first radially slanted guiding surface 1132 provided on the snap-fit groove of the first snap-fit part 1131 facing the rotating-in direction of the second snap-fit mechanism 121 may abut against the second radially slanted guiding surface 1212 provided on the snap-fit hook of the second snap-fit part 1211 facing the rotating-in direction of the first snap-fit mechanism 113. Under the abutting force, the first snap-fit mechanism 113 may elastically deform toward the upward direction shown in FIG. 6, causing the snap-fit hook of the second snap-fit part 1211 to move along the first radially slanted guiding surface 1132 to snap-fit with the snap-fit groove of the first snap-fit part 1131 until the first radially slanted guiding surface 1132 contacts the blocking surface 1134 of the snap-fit groove and abuts against the blocking surface 1134 to block the cover assembly 12 from being further rotated into the opening 111. In some embodiments, there may be provided only one of the first radially slanted guiding surface 1132 and the second radially slanted guiding surface 1212. When only the first radially slanted guiding surface 1132 is provided, the first snap-fit mechanism 113 may elastically deform under the abutting force between the first radially slanted guiding surface 1132 and the circumferential side surface of the cover assembly 12, to cause the snap-fit hook of the second snap-fit part 1211 move along the first radially slanted guiding surface 1132 to snap-fit into the snap-fit groove of the first snap-fit part 1131. When only the second radially slanted guiding surface 1212 is provided, the first snap-fit mechanism 113 may elastically deform under the abutting force between the second radially slanted guiding surface 1212 and the inner wall 112 of the opening 111, to cause the snap-fit hook to move along the inner wall 112 of the opening 111 and snap-fit into the snap-fit groove. At this state, the rotation is completed. The second snap-fit mechanism 121 and the first snap-fit mechanism 113 snap-fit with one another, such that the cover assembly 12 covers the opening 111 of the housing 11. When the rotation of the cover assembly 12 is completed, the second stick body 132 of the joystick assembly 13 may be connected with the first stick body 131 along the direction shown in the dashed line. As shown in FIG. 7, the end of the first stick body 131 penetrating through the cover assembly 12 may be inserted into the mounting hole of the second stick body 132. In some embodiments, the diameter of an end of the second stick body 132 having the mounting hole is not smaller than the diameter of the through hole 124 on the cover assembly 12. In some embodiments, the distance between end having the mounting hole and the cover assembly 12 may satisfy a dustproof condition or requirement. When the second stick body 132 is mounted, the second stick body 132 may occupy the entire through hole 14 to block the external dusts from entering the inside of the housing through the through hole 124. After the second stick body 132 is mounted, the second stick body 132 may be operated by a user to control the joystick assembly 13.

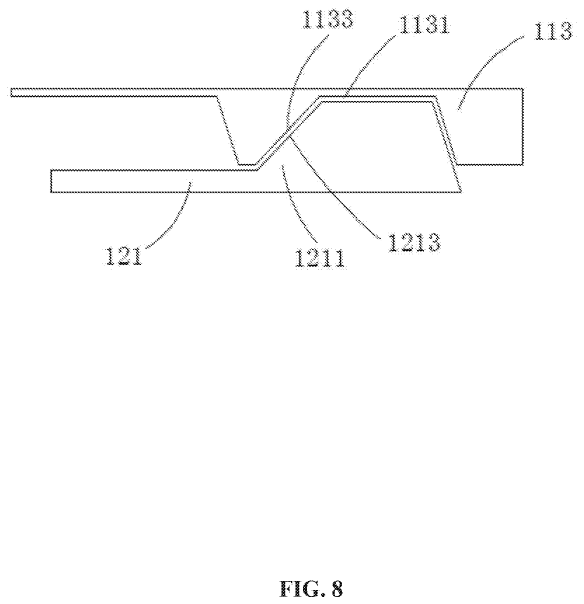

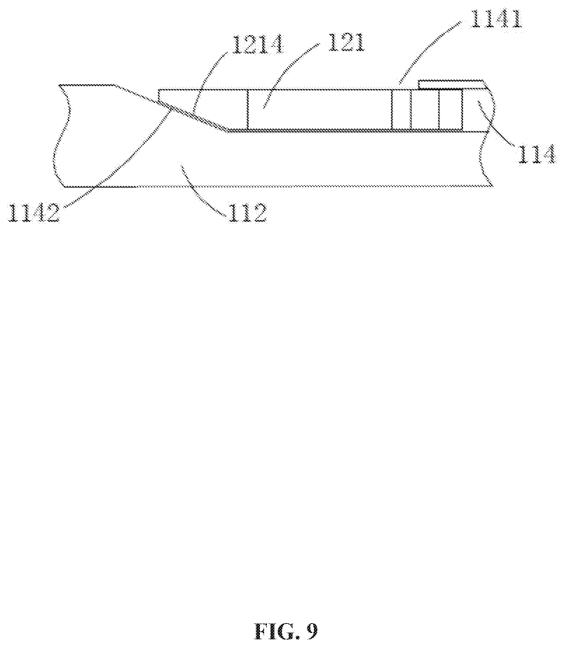

In some embodiments, when the cover assembly 12 is to be detached from the opening 111 of the housing 11, a tool may be used to operate the force bearing member 125 to rotate the cover assembly 12. As shown in FIG. 8, a leftward force may cause the first snap-fit part 1131 to separate from the second snap-fit part 1211. At this state, the first radially slanted guiding surface 1133 disposed on the snap-fit groove of the first snap-fit part 1131 facing the second snap-fit mechanism 121 in a separating direction may abut against the second radially slanted guiding surface 1213 disposed on the snap-fit hook of the second snap-fit part 1211 facing the first snap-fit mechanism 113 in the separating direction. Under the abutting force, the first snap-fit mechanism 113 may elastically deform in the upward direction of FIG. 8, to cause the snap-fit hook of the second snap-fit part 1211 move along the first radially slanted guiding surface 1133 to separate from the first snap-fit part 1131. In some embodiments, only one of the first radially slanted guiding surface 1133 and the second radially slanted guiding surface 1213 is included. When only the first radially slanted guiding surface 1133 is included, the first snap-fit mechanism 113 may elastically deform when the first radially slanted guiding surface 1133 abuts against the cover assembly 12, to cause the snap-fit hook of the second snap-fit part 1211 to move along the first radially slanted guiding surface 1133 to separate from the snap-fit groove. When only the second radially slanted guiding surface 1213 is included, the first snap-fit mechanism 113 may elastically deform when the second radially slanted guiding surface 1213 abuts against the inner wall 112 of the opening 111, to cause the snap-fit hook to move along the inner wall of the opening 111 to separate from the snap-fit groove. After the snap-fit hook of the second snap-fit part 1211 is separated from the first snap-fit part 1131, the cover assembly 12 may be further rotated in the separating direction. When the second snap-fit mechanism 121 is located at the entry/exit port 1141 of the guiding groove 114, as shown in FIG. 9, the first axially slanted guiding surface 1142 and the second axially slanted guiding surface 1214 may abut against one another. Under the abutting force, the second snap-fit mechanism 121 may exit the guiding groove 114 in a direction toward an outside of the housing 11, such that the cover assembly 12 axially separates from the opening 111. In some embodiments, only one of the first axially slanted guiding surface 1142 and the second axially slanted guiding surface 1214 is included. When only the first axially slanted guiding surface 1142 is included, the second snap-fit mechanism 121 may exit the guiding groove 114 in a direction toward an outside of the housing 11 when the second snap-fit mechanism 121 abuts against the firs axially slanted guiding surface 1142. When only the second axially slanted guiding surface 1214 is included, the second snap-fit mechanism 121 may exit the guiding groove 114 in a direction toward an outside of the housing 11 when the second axially slanted guiding surface 1214 abuts against a side wall of the entry/exit port 1141, to cause the cover assembly 12 to axially separate from the opening 111. At this state, the separation process is completed. The cover assembly 12 and the housing 11 are separated.

Different from the existing technologies, the present disclosure provides a first snap-fit mechanism disposed on an inner wall of an opening of the housing. A cover assembly is provided with a second snap-fit mechanism. The first snap-fit mechanism and/or the second snap-fit mechanism are elastic snap-fit mechanisms. The cover assembly and the housing may be connected through the snap-fit coupling between the first snap-fit mechanism and the second snap-fit mechanism. When under an external force, the first snap-fit mechanism and/or the second snap-fit mechanism may elastically deform to release the snap-fit coupling, thereby separating the first snap-fit mechanism and the second snap-fit mechanism. The separation may render it convenient to mount a dust cover on the cover assembly, where the dust cover is configured to block the dusts from entering the housing. When the dust cover needs to be replaced, the disclosed structure renders it convenient to disassemble the dust cover for replacement. When the dust cover is not provided on the cover assembly, the cover assembly may be conveniently mounted to the housing or may be conveniently detached from the housing to clean the dusts accumulated inside the housing.

The present disclosure also provides a remote control device. The remote control device includes the housing assembly described above.

The above descriptions explain in detail the various embodiments of the disclosed structures. The above descriptions use detailed examples to explain the principle and implementation of the disclosed structures. These explanations of the various embodiments are intended to facilitate the understanding of the disclosed structures and the ideas. A person having ordinary skills in the art may modify the detailed implementation and the application scope based on the present disclosure. Thus, the content of the present specification should not be interpreted as being limiting the scope of the present disclosure.

Other embodiments of the present disclosure will be apparent to those skilled in the art from consideration of the specification and practice of the embodiments disclosed herein. It is intended that the specification and examples be considered as example only and not to limit the scope of the present disclosure, with a true scope and spirit of the invention being indicated by the following claims. Variations or equivalents derived from the disclosed embodiments also fall within the scope of the present disclosure.

What is claimed is:

1. A housing assembly for a remote control device, comprising:
a housing comprising an opening, wherein a first snap-fit mechanism is provided on an inner wall of the opening; and
a cover assembly comprising a second snap-fit mechanism, wherein the second snap-fit mechanism is configured to snap-fit with the first snap-fit mechanism to cause the cover assembly to cover the opening of the housing,
wherein at least one of the first snap-fit mechanism or the second snap-fit mechanism is an elastic snap-fit mechanism, wherein when under an external force, at least one of the first snap-fit mechanism or the second snap-fit mechanism elastically deforms to release a snap-fit state to cause the cover assembly to separate from the housing.

2. The housing assembly of claim 1,
wherein the first snap-fit mechanism comprises a first snap-fit part that is a snap-fit groove, and
wherein the second snap-fit mechanism comprises a second snap-fit part that is a snap-fit hook configured to couple with the snap-fit groove.

3. The housing assembly of claim 2,
wherein a first radially slanted guiding surface is provided on the snap-fit groove facing a separating or rotating-in direction of the second snap-fit mechanism, and
wherein when the cover assembly is rotated in the separating or rotating-in direction, the first snap-fit mechanism elastically deforms when the first radially slanted guiding surface abuts against a circumferential side surface of the cover assembly to cause the snap-fit hook to move along the first radially slanted guiding surface to exit from the snap-fit groove or to enter into the snap-fit groove.

4. The housing assembly of claim 2,
wherein a second radially slanted guiding surface is provided on the snap-fit hook facing the separating or rotating-in direction of the first snap-fit mechanism, and
wherein when the cover assembly is rotated in the separating or rotating-in direction, the first snap-fit mechanism elastically deforms when the second radially slanted guiding surface abuts against the inner wall of the opening, to cause the snap-fit hook to move along the inner wall of the opening to separate from the snap-fit groove or to enter into the snap-fit groove.

5. The housing assembly of claim 2,
wherein the second snap-fit mechanism is configured to protrude from a circumferential side surface of the cover assembly,
wherein a circumferential guiding groove is concavely provided on the inner wall of the opening of the housing, the guiding groove comprises an entry/exit port, a first axially slanted guiding surface is provided at a side wall of the entry/exit port facing an outside of the housing, and
wherein when the cover assembly is rotated in the separating or rotating-in direction, the second snap-fit mechanism abuts against the first axially slanted guiding surface, to cause the second snap-fit mechanism to exit the guiding groove in a direction facing the outside of the housing or enter into the guiding groove in a direction facing an inside of the housing, and further to cause the cover assembly to axially separate from or enter into the opening of the housing.

6. The housing assembly of claim 2,
wherein the second snap-fit mechanism is configured to protrude from a circumferential side surface of the cover assembly,
wherein a circumferential guiding groove is concavely provided on the inner wall of the opening of the housing, the guiding groove comprises an entry/exit port, a second axially slanted guiding surface is provided on a side of the second snap-fit mechanism facing an inside of the housing, and
wherein when the cover assembly is rotated in the separating or rotating-in direction, the second axially slanted guiding surface abuts against a side wall of the entry/exit port of the guiding groove, to cause the second snap-fit mechanism to exit the guiding groove in a direction facing an outside of the housing or enter into the guiding groove from a direction facing the inside of the housing, and further to cause the cover assembly to axially separate from or enter into the opening of the housing.

7. The housing assembly of claim 6,
wherein the snap-fit groove comprises a blocking surface, and
wherein when the snap-fit hook snap-fits into the snap-fit groove, the second radially slanted guiding surface abuts against the blocking surface to block the cover assembly from being further rotated into opening.

8. The housing assembly of claim 1,
wherein the cover assembly comprises a hollow body, the second snap-fit mechanism is fixed to the hollow body,
wherein the housing assembly further comprises a joystick assembly configured to penetrate through the hollow body, the joystick assembly comprising:
a first stick body having an end fixedly mounted in the opening of the housing; and
a second stick body having an axial mounting hole at an end,
wherein another end of the first stick body is configured to penetrate through a through hole of the cover assembly and insert into the mounting hole of the second stick body,
wherein a diameter of the end of the second stick body having the mounting hole is not smaller than a diameter of the through hole, and a distance of the end of the second stick body having the mounting hole from the cover assembly satisfies a dustproof condition.

9. The housing assembly of claim 8, the cover assembly further comprises a dust cover covering the hollow body, the dust cover comprising a through hole,
wherein a force bearing member is provided on the hollow body or the dust cover, the force bearing member configured to receive an external force.

10. A remote control device, comprising:
a housing assembly, comprising:
a housing comprising an opening, wherein a first snap-fit mechanism is provided on an inner wall of the opening; and
a cover assembly comprising a second snap-fit mechanism, wherein the second snap-fit mechanism is configured to snap-fit with the first snap-fit mechanism to cause the cover assembly to cover the opening of the housing,
wherein at least one of the first snap-fit mechanism or the second snap-fit mechanism is an elastic snap-fit mechanism, wherein when under an external force, at least one of the first snap-fit mechanism or the second snap-fit mechanism elastically deforms to release a snap-fit state to cause the cover assembly to separate from the housing.
